(19) United States
(12) Patent Application Publication
(10) Pub. No.: US 2004/0149890 A1
(43) Pub. Date: Aug. 5, 2004

(54) Surface-mounting type optical device

(76) Inventor: Shigehiro Yoshida, Tokyo (JP)

Correspondence Address: BIRCH STEWART KOLASCH & BIRCH, PO BOX 747, FALLS CHURCH, VA, 22040-0747, US

(21) Appl. No.: 10/748,249

(22) Filed: Dec. 31, 2003

(30) Foreign Application Priority Data
Jan. 29, 2003 (JP) 2003-20472

(51) Int. Cl. H01L 31/00

(52) U.S. Cl. 250/214.1

(57) ABSTRACT

An surface-mounting type optical device is arranged such that an optical component is attached at the bottom of a resin portion; an electrode is led out from the side of the resin portion; the electrode is connected with a pattern formed on the surface of a substrate; and a step portion used for the engagement of the substrate with the resin portion is formed in part of the resin portion. Thus, the insertion of a disk such as a CD can be detected even when the disk is inserted below the substrate.

### BACKGROUND OF THE INVENTION

1. Field of the Invention

The present invention relates to a surface-mounting type optical device used for detecting the state in which a disk such as a CD is INSERTED (the state in which a disk is inserted in a loading slot) and the state in which the disk is PUSHED (the state in which the disk is pushed from the position of INSERT for loading the disk).

2. Description of Related Art

Conventional surface-mounting type optical devices include a chip device that contains an optical member such as an infrared-emitting diode or a phototransistor, mounted thereon, and that is mounted on the top of a substrate.

Accordingly, when containing an infrared-emitting diode, the chip device can emit light in the upward direction from the substrate, and when containing a phototransistor, the chip device can receive light emitted in the downward direction from above the substrate.

However, because the chip device is mounted on the top of the substrate, it cannot emit light in the downward direction from the substrate, and can not receive light emitted in the upward direction from below the substrate.

By the way, Japanese Patent Publication JP-A04-302115 (pp. 1-2, FIG. 2) discloses a chip device-mounting structure in which a printed substrate has an aperture part (a hole formed therethrough), and a chip device is inserted into the aperture part, in order to reduce the mounting area of the chip device. However, the invention described in the Japanese Patent Publication is not particularly directed to a chip device containing an optical component. Therefore, in the above chip device mounting structure, the chip device is not embedded in the substrate in order to solve the inconvenience that the chip device containing an light-emitting diode cannot emit light in the downward direction from the substrate and the inconvenience that the chip device containing a phototransistor cannot receive light emitted in the upward direction from below the substrate.

The conventional surface-mounting type optical device is arranged as mentioned above. As a result, there is the problem that, although the insertion of a disk such as a CD can be detected when the disk is inserted above the substrate, the insertion of a disk such as a CD cannot be detected when the disk is inserted below the substrate.

### SUMMARY OF THE INVENTION

The present invention has been accomplished to solve the above-mentioned problems. An object of the present invention is to provide a surface-mounting type optical device that can detect the state in which a disk such as a CD is inserted even when the disk is inserted below the substrate.

The surface-mounting type optical device according to the present invention is arranged such that a light-emitting member or a light-receiving member is attached at the bottom of the main body of the optical device; an electrode member is led out from the side of the main body of the optical device, and is connected with a pattern formed on the surface of the substrate; and a step portion used for the engagement of the substrate with the main body of the optical device is formed in part of the main body of the optical device.

Therefore, according to the present invention, the state in which a disk such as a CD is inserted can be detected even when the disk is inserted below the substrate.

### BRIEF DESCRIPTION OF THE DRAWINGS

FIG. 1 is a side view of a surface-mounting type optical device according to a first embodiment of the present invention;

FIG. 2 is an underneath plan view of the surface-mounting type optical device shown in FIG. 1;

FIG. 3 is a side view of the state in which the surface-mounting type optical device shown in FIG. 1 is mounted on a substrate;

FIG. 4 is another side view of the state in which the surface-mounting type optical device shown in FIG. 1 is mounted on a substrate;

FIG. 5 is a perspective view of a surface-mounting type optical device according to a second embodiment of the present invention, as seen from below; and

FIG. 6 is a side view of the state in which the surface-mounting type optical device shown in FIG. 5 is mounted on a substrate.

### DETAILED DESCRIPTION OF THE PREFERRED EMBODIMENTS

An embodiment of the present invention will be described below.

Embodiment 1

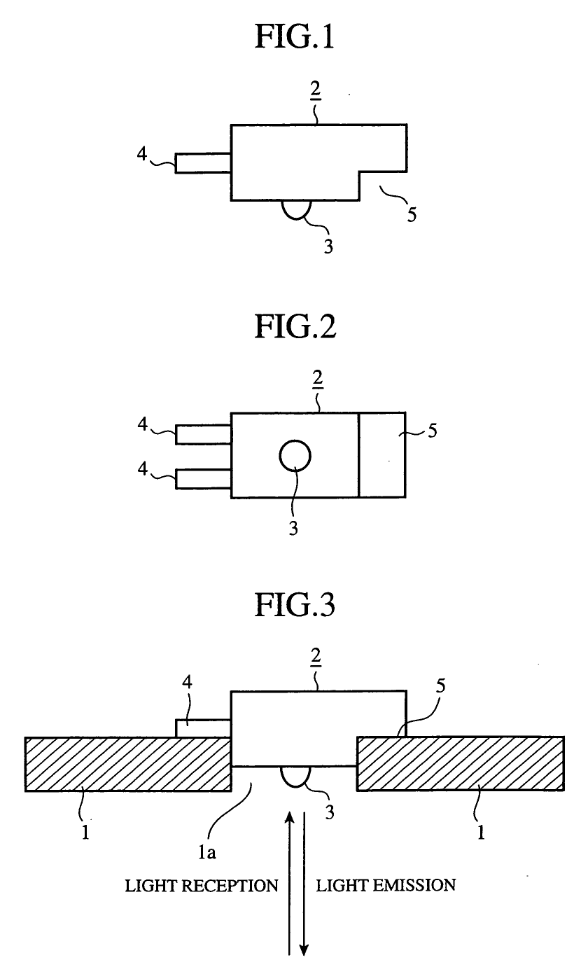

FIG. 1 is a side view of a surface-mounting type optical device according to a first embodiment of the present invention, and FIG. 2 is an underneath plan view of the surface-mounting type optical device shown in FIG. 1. FIG. 3 is a side view of the state in which the surface-mounting type optical device shown in FIG. 1 is mounted on a substrate.

Referring to FIGS. 1-3, a substrate 1 is provided with an engaging hole 1a in which a resin portion 2 is inserted, and the resin portion 2 constitutes the main body of the optical device.

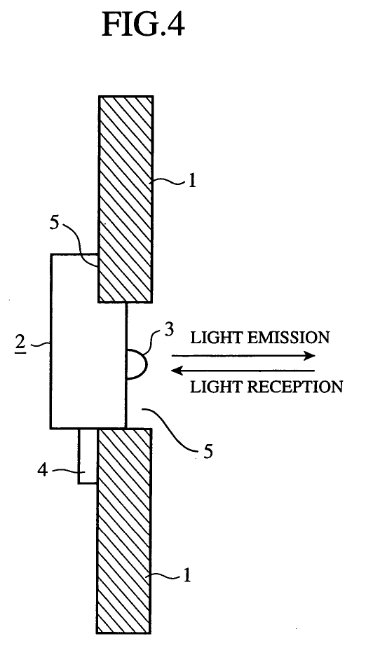

An optical component 3 is attached at the bottom of the resin portion 2, and constitutes an infrared-emitting diode (light-emitting member) that emits light in the downward direction of the substrate 1 (in the interior direction of the substrate 1) or a phototransistor (light-receiving member) that receives light emitted in the upward direction of the substrate 1 (from the interior direction of the substrate 1). However, when the substrate 1 is not set up horizontally as shown in FIG. 3, but the substrate 1 is set up vertically as shown in FIG. 4, the optical component 3 emits light in the direction of the right with respect to the substrate 1 or receives light emitted from the direction of the right with respect to the substrate 1. In this case, the direction of the right with respect to the substrate 1 is herein treated as “the interior direction of the substrate 1.”

An electrode 4 is led out from the side of the resin portion 2, is connected to a pattern (not shown) formed on the surface of the substrate 1, and electrically connects the pattern and the optical component 3. The electrode 4 constitutes an electrode member.

A step portion 5 is formed on the side of the resin portion 2, which is opposite the side thereof from which the electrode 4 is led out, in order to engage the substrate 1, thereby stably supporting the resin portion 2.

The operation will now be described as below.

The surface-mounting type optical device according to the first embodiment is arranged such that the optical component 3 is attached at the bottom of the resin portion 2, and from the side of the resin portion 2 is led out the electrode 4, as shown in FIG. 1 and FIG. 2. Moreover, the surface-mounting type optical device is arranged such that the step portion 5 is formed on the side of the resin portion 2, which is opposite the side thereof from which the electrode 4 is led out, in order to stably support the resin portion 2.

In addition, when mounting the surface-mounting type optical device on the substrate 1, the resin portion 2 is inserted in an engaging hole 1a of the substrate 1, and the electrode 4 is soldered to a pattern formed on the surface of the substrate 1 with creamy solder such that the step portion 5 of the surface-mounting type optical device engages the substrate 1.

Thus, not only the soldering of the electrode 4 to the pattern supports the resin portion 2, but also the step portion 5 supports the resin portion 2, which makes it possible to suppress the variation of the optical axis of the optical component 3.

As is evident from the above description, according to the first embodiment, it is arranged that the optical component 3 be attached at the bottom of the resin portion 2; the electrode 4 be led out from the side of the resin portion 2; the electrode 4 be connected with the pattern formed on the surface of the substrate 1; and the step portion 5 used for the engagement of the substrate 1 with the resin portion 2 be formed in part of the resin portion 2. For this reason, even when a disk such as a CD is inserted below the substrate 1 (in the direction of the interior of the substrate 1), the insertion of the disk can be detected.

Additionally, according to the first embodiment, it is arranged that the step portion 5 be formed on the side of the resin portion 2, which is opposite the side thereof from which the electrode 4 is led out, thereby supporting stably the resin portion 2.

Embodiment 2

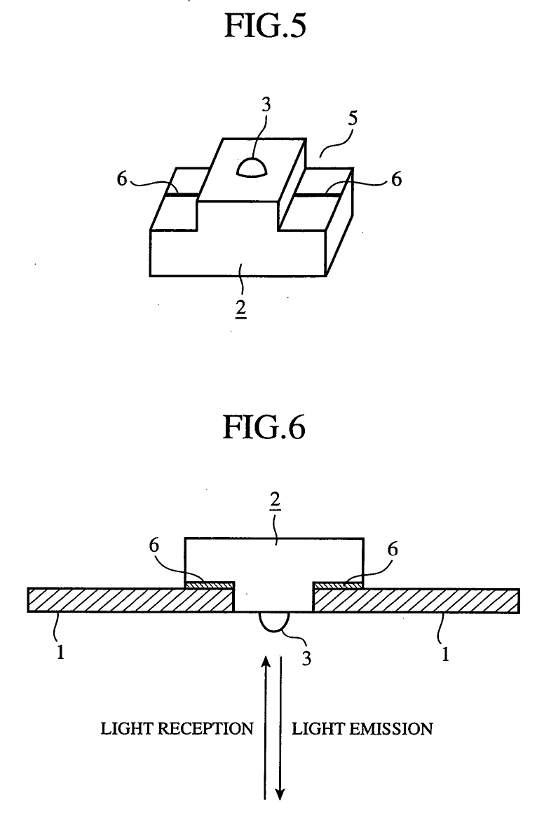

In the first embodiment, a surface-mounting type optical device is described such that the step portion 5 engages the substrate 1 and the resin portion 2 is described. However, in order to more positively suppress the variation of the optical axis of the optical component 3, it maybe arranged that, instead of leading out the electrode 4 from the side of the resin portion 2, fixing electrodes 6 used for fixing the resin portion 2 to the substrate 1 be formed on the step portions 5 as shown in FIG. 5, and the fixing electrodes 6 be fixed to the substrate 1 with creamy solder when mounting the surface-mounting type optical device on the substrate 1 (see FIG. 6).

For this reason, a surface-mounting type optical device can be produced such that the variation of its optical axis is greatly reduced.

What is claimed is:

1. A surface-mounting type optical device comprising:
a light-emitting member that is attached at the bottom of the main body of the optical device a portion of which is inserted in the engaging hole of a substrate, and that emits light in the interior direction of the substrate;
an electrode member that is led out from the side of the main body of the optical device, is connected to a pattern formed on the surface of the substrate, and electrically connects the pattern and the light-emitting member; and
a step portion that is formed in part of the main body of the optical device, and engages the substrate.

2. The surface-mounting type optical device according to claim 1, wherein the step portion is formed on the side of the main body of the optical device, which is opposite the side thereof from which the electrode member is led out.

3. A surface-mounting type optical device comprising:
a light-receiving member that is attached at the bottom of the main body of the optical device a portion of which is inserted in the engaging hole of a substrate, and that receives light emitted from the interior direction of the substrate;
an electrode member that is led out from the side of the main body of the optical device, is connected to a pattern formed on the surface of the substrate, and electrically connects the pattern and the light-receiving member; and
a step portion that is formed in part of the main body of the optical device, and engages the substrate.

4. The surface-mounting type optical device according to claim 3, wherein the step portion is formed on the side of the main body of the optical device, which is opposite the side thereof from which the electrode member is led out.

5. A surface-mounting type optical device comprising:
a light-emitting member that is attached at the bottom of the main body of the optical device a portion of which is inserted in the engaging hole of a substrate, and that emits light in the interior direction of the substrate;
a step portion that is formed in part of the main body of the optical device, and engages the substrate; and
a fixing electrode that is formed on the step portion, is connected to a pattern formed on the surface of the substrate, and electrically connects the pattern and the light-emitting member.

6. A surface-mounting type optical device comprising:
a light-receiving member that is attached at the bottom of the main body of the optical device a portion of which is inserted in the engaging hole of a substrate, and that receives light emitted from the direction of the interior of the substrate;
a step portion that is formed in part of the main body of the optical device, and engages the substrate; and
a fixing electrode that is formed on the step portion, is connected to a pattern formed on the surface of the substrate, and electrically connects the pattern and the light-receiving member.
